(19) United States
(12) Patent Application Publication
(10) Pub. No.: US 2024/0023451 A1
(43) Pub. Date: Jan. 18, 2024

(54) PIEZOELECTRIC FILM

(71) Applicant: FUJIFILM Corporation, Tokyo (JP)

(72) Inventor: Misato NARUBAYASHI, Minamiashigara-shi (JP)

(73) Assignee: FUJIFILM Corporation, Tokyo (JP)

(21) Appl. No.: 18/478,009

(22) Filed: Sep. 29, 2023

Related U.S. Application Data
(63) Continuation of application No. PCT/JP2022/011628, filed on Mar. 15, 2022.

(30) Foreign Application Priority Data
Mar. 30, 2021 (JP) 2021-056609

(51) Int. Cl. H10N 30/85; H04R 17/00; H10N 30/092; C08K 3/22

(52) U.S. Cl. CPC H10N 30/852; H04R 17/005; H10N 30/092; C08K 3/22; C08K 2003/2244; C08K 2201/001; C08K 2201/005

(57) ABSTRACT

Provided is a piezoelectric film that is capable of suppressing a decrease in sound pressure even in a case of being repeatedly bent and stretched and has high durability. The piezoelectric film is a piezoelectric film including a piezoelectric layer consisting of a polymer-based piezoelectric composite material that contains piezoelectric particles in a matrix containing a polymer material, and electrode layers formed on both surfaces of the piezoelectric layer, in which at least one surface of the piezoelectric layer has a plurality of recesses with a depth of 1 μm or greater, the recesses have a number density of 100 to 1,000 pc/mm², and the at least one surface has a kurtosis Rku of 2.9 to 25.

### CROSS-REFERENCE TO RELATED APPLICATIONS

This application is a Continuation of PCT International Application No. PCT/JP2022/011628 filed on Mar. 15, 2022, which claims priority under 35 U.S.C. § 119(a) to Japanese Patent Application No. 2021-056609 filed on Mar. 30, 2021. The above applications are hereby expressly incorporated by reference, in their entirety, into the present application.

### BACKGROUND OF THE INVENTION

### 1. Field of the Invention

The present invention relates to a piezoelectric film.

### 2. Description of the Related Art

With reduction in thickness of displays such as liquid crystal displays or organic EL displays, speakers used in these thin displays are also required to be lighter and thinner. Further, in flexible displays having flexibility, speakers are also required to have flexibility in order to be integrated with flexible displays without impairing lightness and flexibility. As such lightweight, thin, and flexible speakers, it is considered to employ sheet-like piezoelectric films having a property of stretching and contracting in response to an applied voltage.

It is also considered that a speaker having flexibility is obtained by bonding an exciter having flexibility to a vibration plate having flexibility. An exciter is an exciton that vibrates an article and produces a sound by being brought into contact with various articles and being attached thereto.

It has been suggested to use a piezoelectric composite material containing piezoelectric particles in a matrix as a sheet-like piezoelectric film having flexibility or an exciter.

For example, JP2014-014063A describes a piezoelectric film including a polymer-based piezoelectric composite material obtained by dispersing piezoelectric particles in a viscoelastic matrix formed of a polymer material having viscoelasticity at room temperature, thin film electrodes formed on both surfaces of the polymer-based piezoelectric composite material, and a protective layer formed on a surface of the thin film electrode.

### SUMMARY OF THE INVENTION

Here, according to the examination conducted by the present inventors, it was found that the durability may be problematic due to a decrease in sound pressure in a case of repeatedly bending and stretching a piezoelectric film that includes a polymer-based piezoelectric composite material formed by dispersing piezoelectric particles in a matrix consisting of a polymer material and electrode layers formed on both surfaces of the polymer-based piezoelectric composite material.

An object of the present invention is to solve such a problem of the related art and to provide a piezoelectric film that is capable of suppressing a decrease in sound pressure even in a case of being repeatedly bent and stretched and has high durability.

In order to achieve the above-described object, the present invention has the following configurations.

[1] A piezoelectric film comprising: a piezoelectric layer consisting of a polymer-based piezoelectric composite material that contains piezoelectric particles in a matrix containing a polymer material; and electrode layers formed on both surfaces of the piezoelectric layer, in which at least one surface of the piezoelectric layer has a plurality of recesses with a depth of 1 μm or greater, the recesses have a number density of 100 to 1,000 pc/mm², and the at least one surface has a kurtosis Rku of 2.9 to 25.

[2] The piezoelectric film according to [1], in which the piezoelectric particles have an average particle diameter of 0.5 μm to 5 μm.

[3] The piezoelectric film according to [1] or [2], in which the at least one surface of the piezoelectric layer has a surface roughness Ra of 10 nm to 200 nm.

[4] The piezoelectric film according to any one of [1] to [3], in which the piezoelectric layer includes a piezoelectric layer main body and an interlayer.

According to the present invention described above, it is possible to provide a piezoelectric film that is capable of suppressing a decrease in sound pressure even in a case of being repeatedly bent and stretched and has high durability.

### BRIEF DESCRIPTION OF THE DRAWINGS

FIG. 1 is a view conceptually illustrating an example of a piezoelectric film of the present invention.

FIG. 2 is a partially enlarged view conceptually illustrating a surface shape of a piezoelectric layer.

FIG. 3 is a conceptual view for describing a kurtosis Rku.

FIG. 4 is a conceptual view for describing a kurtosis Rku.

FIG. 5 is a view for describing a state of a stress in a case where the piezoelectric film is bent.

FIG. 6 is a partially enlarged view conceptually illustrating the surface shape of a piezoelectric layer of the related art.

FIG. 7 is a partially enlarged view conceptually illustrating the surface shape of the piezoelectric layer in a case where the Rku is large.

FIG. 8 is a partially enlarged view conceptually illustrating the surface shape of the piezoelectric layer in a case where the Rku is small.

FIG. 9 is a conceptual view for describing an example of a method of preparing a piezoelectric film.

FIG. 10 is a conceptual view for describing an example of the method of preparing a piezoelectric film.

FIG. 11 is a conceptual view for describing an example of the method of preparing a piezoelectric film.

FIG. 12 is a conceptual view for describing an example of the method of preparing a piezoelectric film.

FIG. 13 is a view conceptually illustrating an example of a piezoelectric element including the piezoelectric film of the present invention.

FIG. 14 is a view conceptually illustrating another example of the piezoelectric element including the piezoelectric film of the present invention.

### DESCRIPTION OF THE PREFERRED EMBODIMENTS

Hereinafter, the piezoelectric film according to the embodiment of the present invention will be described in detail based on the preferred embodiments shown in the accompanying drawings.

The description of configuration requirements described below may be made based on typical embodiments of the present invention, but the present invention is not limited to such embodiments.

In addition, in the present specification, a numerical range shown using “to” indicates a range including numerical values described before and after “to” as a lower limit and an upper limit.

[Piezoelectric Film]

A piezoelectric film according to the embodiment of the present invention is a piezoelectric film including a piezoelectric layer consisting of a polymer-based piezoelectric composite material that contains piezoelectric particles in a matrix containing a polymer material, and electrode layers formed on both surfaces of the piezoelectric layer, in which at least one surface of the piezoelectric layer has a plurality of recesses with a depth of 1 μm or greater, the recesses have a number density of 100 to 1,000 pc/mm², and the surface has a kurtosis Rku of 2.9 to 25.

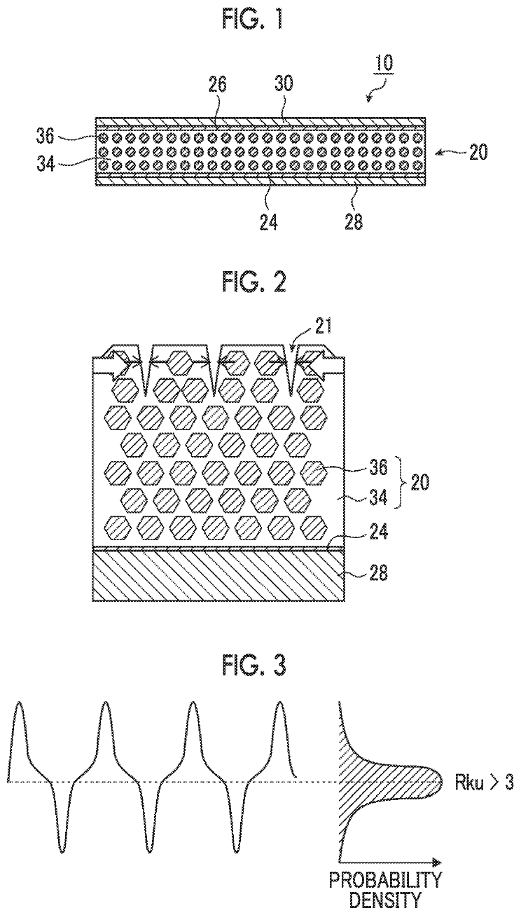

FIG. 1 conceptually illustrates an example of the piezoelectric film according to the embodiment of the present invention.

As illustrated in FIG. 1, the piezoelectric film 10 includes a piezoelectric layer 20 which is a sheet-like material having piezoelectric characteristics, a first electrode layer 24 laminated on one surface of the piezoelectric layer 20, a first protective layer 28 laminated on the first electrode layer 24, a second electrode layer 26 laminated on the other surface of the piezoelectric layer 20, and a second protective layer 30 laminated on the second electrode layer 26.

The piezoelectric layer 20 consists of a polymer-based piezoelectric composite material containing the piezoelectric particles 36 in a matrix 34 containing a polymer material. In addition, the first electrode layer 24 and the second electrode layer 26 are electrode layers of the present invention.

As will be described later, the piezoelectric film 10 (piezoelectric layer 20) is polarized in the thickness direction as a preferred embodiment.

As an example, the piezoelectric film 10 is used in various acoustic devices (audio equipment) such as speakers, microphones, and pickups used in musical instruments such as guitars, to generate (reproduce) a sound due to vibration in response to an electrical signal or convert vibration due to a sound into an electrical signal.

Further, the piezoelectric film can also be used in pressure sensitive sensors, power generation elements, and the like in addition to the examples described above.

Alternatively, the piezoelectric film can also be used as an exciter that vibrates an article and generates a sound by being brought into contact with and attached to various articles.

In the piezoelectric film 10, the second electrode layer 26 and the first electrode layer 24 form a pair of electrodes. That is, the piezoelectric film 10 has a configuration in which both surfaces of the piezoelectric layer 20 are sandwiched between the electrode pair, that is, the first electrode layer 24 and the second electrode layer 26, and the laminate is further sandwiched between the first protective layer 28 and the second protective layer 30.

As described above, in the piezoelectric film 10, the region sandwiched between the first electrode layer 24 and the second electrode layer 26 stretches and contracts according to the applied voltage.

Further, the first electrode layer 24 and the first protective layer 28, and the second electrode layer 26 and the second protective layer 30 are named according to the polarization direction of the piezoelectric layer 20. Therefore, the first electrode layer 24 and the second electrode layer 26, and the first protective layer 28 and the second protective layer 30 have configurations that are basically the same as each other.

Further, in addition to the above-described layers, the piezoelectric film 10 may include an insulating layer that covers a region where the piezoelectric layer 20 on a side surface or the like is exposed for preventing a short circuit or the like.

In a case where a voltage is applied to the first electrode layer 24 and the second electrode layer 26 of the piezoelectric film 10, the piezoelectric particles 36 stretch and contract in the polarization direction according to the applied voltage. As a result, the piezoelectric film 10 (piezoelectric layer 20) contracts in the thickness direction. At the same time, the piezoelectric film 10 stretches and contracts in the in-plane direction due to the Poisson's ratio. The degree of stretch and contraction is approximately in a range of 0.01% to 0.1%. In the in-plane direction, the stretch and contraction are isotropically made in all directions.

The thickness of the piezoelectric layer 20 is preferably approximately in a range of 10 to 300 μm. Therefore, the degree of stretch and contraction in the thickness direction is as extremely small as approximately 0.3 μm at the maximum.

On the contrary, the piezoelectric film 10, that is, the piezoelectric layer 20, has a size much larger than the thickness in the plane direction. Therefore, for example, in a case where the length of the piezoelectric film 10 is 20 cm, the piezoelectric film 10 stretches and contracts by a maximum of approximately 0.2 mm by the application of a voltage.

Further, in a case where a pressure is applied to the piezoelectric film 10, electric power is generated by the action of the piezoelectric particles 36.

By utilizing this, the piezoelectric film 10 can be used for various applications such as a speaker, a microphone, and a pressure sensitive sensor as described above.

Here, in the piezoelectric film 10 according to the embodiment the present invention, at least one surface of the piezoelectric layer 20, that is, a surface of the piezoelectric layer 20 in contact with the electrode layer has a plurality of recesses with a depth of 1 μm or greater, the recesses have a number density of 100 to 1,000 pc/mm², and the surface has a kurtosis Rku of 2.9 to 25.

FIG. 2 is a view in which illustration of the second protective layer 30 and the second electrode layer 26 is omitted from the piezoelectric film 10. As illustrated in FIG. 2, the surface of the piezoelectric layer 20 has fine recesses 21 with a predetermined number density, and the kurtosis Rku in the roughness curve due to irregularities is in a range of −2.9 to 25.

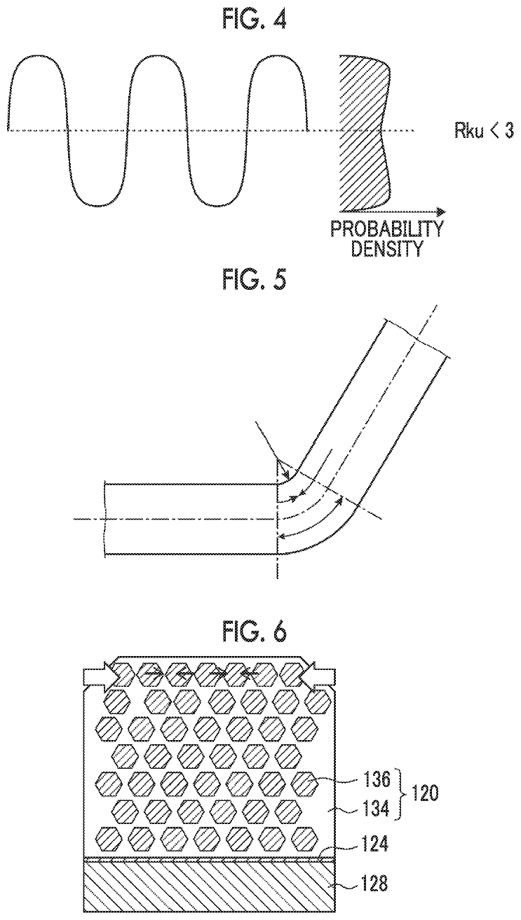

The kurtosis Rku represents the fourth power average of Z (x) at a reference length non-dimensionalized by the fourth power of the root-mean-square height (Zq). The kurtosis Rku represents the sharpness of the surface and has a normal distribution in a case of “Rku=3”. As illustrated in FIG. 3, “Rku>3” denotes that the surface has a plurality of sharp irregularities, and as illustrated in FIG. 4, “Rku<3” denotes that the surface has few sharp irregularities and is thus flat.

As described above, it was found that the durability may be problematic due to a decrease in sound pressure in a case of repeatedly bending and stretching the piezoelectric film that includes a polymer-based piezoelectric composite material formed by dispersing piezoelectric particles in a matrix consisting of a polymer material and electrode layers formed on both surfaces of the polymer-based piezoelectric composite material.

According to the examination conducted by the present inventor, in a case where the piezoelectric film is bent as illustrated in FIG. 5, a compressive stress is applied to a region inside the bending from the center in the thickness direction, and a tensile stress is applied to a region outside the center. It was found that the piezoelectric layer is damaged by the compressive stress and the tensile stress, and thus the sound pressure is decreased.

Specifically, in regard to the compressive stress, in a case where the surface of the piezoelectric layer is flat as in a case of a piezoelectric film of the related art illustrated in FIG. 6, the piezoelectric particles come into contact with each other in a case of application of the compressive stress to a region in the vicinity of the surface of the piezoelectric layer so that the crystals of the piezoelectric particles are damaged, and thus appropriate piezoelectric characteristics may not be obtained. Therefore, the sound pressure is considered to be decreased.

On the contrary, as in the piezoelectric film according to the embodiment of the present invention illustrated in FIG. 2, since the surface of the piezoelectric layer has recesses, a compressive stress can be absorbed by a plurality of recesses with a depth of 1 μm or greater even in a case where the compressive stress is applied to a region in the vicinity of the surface of the piezoelectric layer, and thus damage to the piezoelectric layer can be prevented and appropriate piezoelectric characteristic can be obtained. Therefore, a decrease in sound pressure can be suppressed.

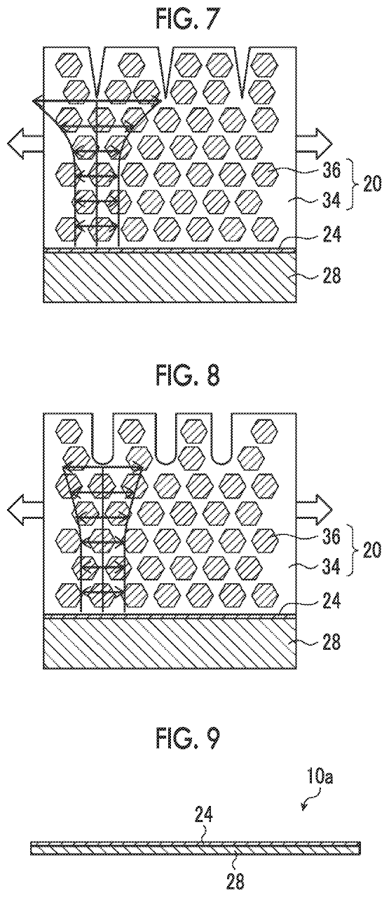

Further, in regard to the tensile stress, even though the surface of the piezoelectric layer has recesses, in a case where recesses are sharp, that is, the kurtosis Rku is extremely large as illustrated in FIG. 7, a stress is concentrated on tip portions of recesses in a case of application of a tensile stress to a region in the vicinity of the surface of the piezoelectric layer, and thus the piezoelectric layer is damaged. Therefore, it is considered that an appropriate piezoelectric characteristics cannot be obtained and the sound pressure is decreased.

On the contrary, in a case where the recesses are round, that is, the kurtosis Rku is small as illustrated in FIG. 8, stress concentration on the tip portions of the recesses can be suppressed even in a case where a tensile stress is applied to a region in the vicinity of the surface of the piezoelectric layer, and thus damage to the piezoelectric layer can be prevented. Therefore, appropriate piezoelectric characteristics can be obtained, and a decrease in sound pressure can be suppressed. Meanwhile, in a case where the kurtosis Rku is extremely small, since the filling ratio of the piezoelectric layer is decreased, sufficient piezoelectric characteristics cannot be obtained, and the sound pressure is decreased.

From the above-described viewpoint, at least one surface of the piezoelectric layer 20 in the piezoelectric film according to the embodiment of the present invention has a plurality of recesses with a depth of 1 μm or greater, the recesses have a number density of 100 to 1,000 pc/mm², and the surface has a kurtosis Rku of 2.9 to 25. Since the surface of the piezoelectric layer in the piezoelectric film according to the embodiment of the present invention has a plurality of recesses, the compressive stress in a case of bending the piezoelectric film can be absorbed, and the stress concentration in a case of application of the tensile stress can be suppressed by setting the kurtosis Rku of the surface to 2.9 or greater. Therefore, damage to the piezoelectric layer caused by repeatedly bending and stretching the piezoelectric film can be prevented, and accordingly, a piezoelectric film capable of preventing a decrease in sound pressure and having high durability can be obtained. In addition, the filling ratio of the piezoelectric layer is ensured and sufficient piezoelectric characteristics can be obtained by setting the kurtosis Rku to 25 or less, and accordingly, a piezoelectric film with a high sound pressure (high conversion efficiency) can be obtained.

From the viewpoint of further improving the durability and obtaining a high sound pressure, the kurtosis Rku is preferably in a range of 3 to 22, more preferably in a range of 4 to 20, and still more preferably in a range of 4.5 to 10.

The kurtosis Rku is acquired in conformity with JIS B 0601:2013 by exposing the surface of the piezoelectric layer coming into contact with the electrode layer and measuring the profile data of the surface roughness of the piezoelectric layer.

Specifically, for example, first, a 5 mol/L NaOH aqueous solution is added dropwise to the protective layer at 15° C. to 25° C. for dissolution. In this case, a part of the electrode layer may be dissolved, and the electrode layer is allowed to stand for a time during which the NaOH aqueous solution does not come into contact with the piezoelectric layer. The NaOH aqueous solution that has stood is washed with pure water, and the exposed electrode layer is dissolved in a ferric chloride aqueous solution at a concentration of 0.01 mol/L to 0.1 mol/L. The dissolution in the ferric chloride aqueous solution is set such that the time after the exposure of the piezoelectric layer does not exceed 5 minutes. The exposed piezoelectric layer is washed with pure water and dried at 30° C. or lower.

Next, the kurtosis Rku is calculated by measuring the profile of the surface roughness of the piezoelectric layer under conditions of a white LED light source (green filter), an objective lens at a magnification of 10 times, an internal lens at a magnification of 0.55 times, a charge coupled device (CCD): 1,280×960 pixel, VSI/VXI, an observation visual field of 825.7 μm×619.3 μm, and a cross-section sampling of 0.645 μm using a non-contact three-dimensional surface shape roughness meter (manufactured by Bruker), setting 0 as an average value, making correction of cylinder inclination, performing fitting with Gaussian process regression, and acquiring the surface roughness. The kurtosis Rku is measured for each of 10 observation visual fields, and an average value thereof is acquired.

Here, from the viewpoint of absorbing the compressive stress in a case of application of the compressive stress, it is preferable that the number density of recesses is large. Meanwhile, in a case where the number density of recesses is extremely large, the filling ratio of the piezoelectric layer is decreased, and thus the sound pressure may not be sufficiently obtained. From the above-described viewpoint, the number density of the recesses having a depth of 1 μm or greater is preferably in a range of 150 to 800 pc/mm², more preferably in a range of 200 to 600 pc/mm², and still more preferably in a range of 300 to 400 pc/mm².

The number density of the recesses is calculated from the surface roughness acquired in the same manner as in the measurement of the kurtosis Rku described above by dissolving the protective layer and the electrode layer, measuring the exposed surface of the piezoelectric layer using a non-contact three-dimensional surface shape roughness meter, making inclination correction, and performing fitting with Gaussian process regression.

Further, from the viewpoint of further improving the durability, the surface roughness Ra of at least one surface of the piezoelectric layer is preferably in a range of 10 nm to 200 nm, more preferably in a range of 30 nm to 240 nm, and still more preferably in a range of 65 nm to 230 nm.

The surface roughness Ra is calculated in the same manner as in the measurement of the kurtosis Rku described above by dissolving the protective layer and the electrode layer, measuring the exposed surface of the piezoelectric layer using a non-contact three-dimensional surface shape roughness meter, making inclination correction, performing fitting with Gaussian process regression, and acquiring the surface roughness. The surface roughness Ra is measured for each of 10 observation visual fields, and the average value is obtained.

Here, in the example illustrated in FIG. 1, the piezoelectric layer is formed of a single layer of a polymer-based piezoelectric composite material containing piezoelectric particles in a matrix that contains a polymer material, but the present invention is not limited thereto, and the piezoelectric layer may be configured to include a piezoelectric layer main body and an interlayer.

The piezoelectric layer main body is a layer consisting of a polymer-based piezoelectric composite material containing piezoelectric particles in a matrix that contains a polymer material.

The interlayer is a layer other than a layer consisting of a polymer-based piezoelectric composite material, and examples thereof include an adhesive layer for adhering the piezoelectric layer main body and the electrode layer to each other, and a layer containing piezoelectric particles having an average particle diameter different from that of the piezoelectric layer main body. For example, the same material as the matrix of the piezoelectric layer or a material close to the matrix can be used as the adhesive layer. Alternatively, a material that can be used as a matrix described below may be used as the adhesive layer. The layer containing the piezoelectric particles having an average particle diameter different from that of the piezoelectric layer main body is capable of filling the irregularities on the surface of the piezoelectric layer main body and further increasing the filling ratio of the piezoelectric particles by being formed, as a layer having an average particle diameter of the piezoelectric particles smaller than that of the piezoelectric layer main body, on the piezoelectric layer main body as an interlayer.

In a case where the piezoelectric layer includes the interlayer, for example, the piezoelectric film has a configuration in which the first protective layer, the first electrode layer, the piezoelectric layer main body, the interlayer, the second electrode layer, and the second protective layer are laminated in this order.

In a case where the piezoelectric layer includes the interlayer, the surface of the interlayer may have recesses having a depth of 1 μm or greater with a number density of 100 to 1000 pc/mm², and the kurtosis Rku may be in a range of −2.9 to 25.

<Piezoelectric Layer (Piezoelectric Layer Main Body)>

The piezoelectric layer is a layer consisting of a polymer-based piezoelectric composite material that contains piezoelectric particles in a matrix containing a polymer material and is a layer that exhibits a piezoelectric effect in which the layer is stretched and contracted in a case where a voltage is applied.

In the piezoelectric film 10, as a preferred embodiment, the piezoelectric layer 20 consists of a polymer-based piezoelectric composite material in which piezoelectric particles 36 are dispersed in the matrix 34 consisting of a polymer material having viscoelasticity at room temperature. Further, in the present specification, the “room temperature” indicates a temperature range of approximately 0° C. to 50° C.

The piezoelectric film 10 according to the embodiment of the present invention is suitably used for a speaker having flexibility such as a speaker for a flexible display. Here, it is preferable that the polymer-based piezoelectric composite material (piezoelectric layer 20) used for a speaker having flexibility satisfies the following requirements. Therefore, it is preferable that a polymer material having viscoelasticity at room temperature is used as a material satisfying the following requirements.

(i) Flexibility

For example, in a case of being gripped in a state of being loosely bent like a document such as a newspaper or a magazine as a portable device, the piezoelectric film is continuously subjected to large bending deformation from the outside at a relatively slow vibration of less than or equal to a few Hz. In this case, in a case where the polymer-based piezoelectric composite material is hard, a large bending stress is generated to that extent, and a crack is generated at the interface between a polymer matrix and piezoelectric particles, which may lead to breakage. Accordingly, the polymer-based piezoelectric composite material is required to have suitable flexibility. In addition, in a case where strain energy is diffused into the outside as heat, the stress is able to be relaxed. Therefore, the polymer-based piezoelectric composite material is required to have a suitably large loss tangent.

(ii) Acoustic Quality

In a speaker, the piezoelectric particles vibrate at a frequency of an audio band of 20 Hz to 20 kHz, and the vibration energy causes the entire polymer-based piezoelectric composite material (piezoelectric film) to vibrate integrally so that a sound is reproduced. Therefore, in order to increase the transmission efficiency of the vibration energy, the polymer-based piezoelectric composite material is required to have appropriate hardness. In addition, in a case where the frequencies of the speaker are smooth as the frequency characteristic thereof, an amount of change in acoustic quality in a case where the lowest resonance frequency is changed in association with a change in the curvature of the speaker decreases. Therefore, the polymer-based piezoelectric composite material is required to have a suitably large loss tangent.

That is, the polymer-based piezoelectric composite material is required to exhibit a behavior of being hard with respect to a vibration of 20 Hz to 20 kHz and being flexible with respect to a vibration of less than or equal to a few Hz. In addition, the loss tangent of a polymer-based piezoelectric composite material is required to be suitably large with respect to the vibration of all frequencies of 20 kHz or less.

In general, a polymer solid has a viscoelasticity relaxing mechanism, and a molecular movement having a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 20), the polymer-based piezoelectric composite material exhibiting a behavior of being rigid with respect to a vibration of 20 Hz to 20 kHz and being flexible with respect to a vibration of less than or equal to a few Hz is realized by using a polymer material whose glass transition point is room temperature, that is, a polymer material having a viscoelasticity at room temperature as a matrix. In particular, from the viewpoint that such a behavior is suitably exhibited, it is preferable that a polymer material in which the glass transition point at a frequency of 1 Hz is at room temperature, that is, in a range of 0° C. to 50° C. is used for a matrix of the polymer-based piezoelectric composite material.

As the polymer material having a viscoelasticity at room temperature, various known materials can be used. It is preferable that a polymer material in which the maximal value of a loss tangent Tanδ at a frequency of 1 Hz according to a dynamic viscoelasticity test at room temperature, that is, in a range of 0° C. to 50° C. is 0.5 or greater is used as the polymer material. In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at room temperature, it is preferable that a storage elastic modulus (E′) at a frequency of 1 Hz according to the dynamic viscoelasticity measurement is 100 MPa or greater at 0° C. and 10 MPa or less at 50° C. In this manner, the bending moment generated in a case where the polymer-based piezoelectric composite material is slowly bent due to the external force can be reduced, and the polymer-based piezoelectric composite material can exhibit a behavior of being rigid with respect to an acoustic vibration of 20 Hz to 20 kHz.

In addition, it is more suitable that the relative dielectric constant of the polymer material having a viscoelasticity at room temperature is 10 or greater at 25° C. Accordingly, in a case where a voltage is applied to the polymer-based piezoelectric composite material, a higher electric field is applied to the piezoelectric particles in the polymer matrix, and thus a large deformation amount can be expected. However, in consideration of ensuring satisfactory moisture resistance and the like, it is suitable that the relative dielectric constant of the polymer material is 10 or less at 25° C.

Examples of the polymer material having a viscoelasticity at room temperature and satisfying such conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, it is preferable to use a material containing a cyanoethyl group and particularly preferable to use cyanoethylated PVA as the polymer material. Further, these polymer materials may be used alone or in combination (mixture) of a plurality of kinds thereof.

In the matrix 34 for which such a polymer material having a viscoelasticity at room temperature is used, a plurality of polymer materials may be used in combination as necessary. That is, other dielectric polymer materials may be added to the matrix 34 for the purpose of adjusting dielectric properties or mechanical properties, in addition to the viscoelastic material such as cyanoethylated PVA as necessary.

Examples of the dielectric polymer material that can be added thereto include a fluorine-based polymer such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, or a polyvinylidene fluoride-tetrafluoroethylene copolymer, a polymer containing a cyano group or a cyanoethyl group such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, or cyanoethyl sorbitol, and synthetic rubber such as nitrile rubber or chloroprene rubber. Among these, a polymer material containing a cyanoethyl group is suitably used.

Further, the number of kinds of the dielectric polymer materials to be added to the matrix 34 of the piezoelectric layer 20 in addition to the material having a viscoelasticity at room temperature, such as cyanoethylated PVA, is not limited to one, and a plurality of kinds of the materials may be added.

In addition, for the purpose of adjusting the glass transition point Tg, a thermoplastic resin such as a vinyl chloride resin, polyethylene, polystyrene, a methacrylic resin, polybutene, or isobutylene, and a thermosetting resin such as a phenol resin, a urea resin, a melamine resin, an alkyd resin, or mica may be added to the matrix 34 in addition to the dielectric polymer materials. Further, for the purpose of improving the pressure sensitive adhesiveness, a viscosity imparting agent such as rosin ester, rosin, terpene, terpene phenol, or a petroleum resin may be added.

In the matrix 34 of the piezoelectric layer 20, the addition amount in a case of adding materials other than the polymer material having viscoelasticity such as cyanoethylated PVA is not particularly limited, but is preferably set to 30% by mass or less in terms of the proportion of the materials in the matrix 34. In this manner, the characteristics of the polymer material to be added can be exhibited without impairing the viscoelasticity relaxing mechanism in the matrix 34, and thus preferable results, for example, an increase in the dielectric constant, improvement of the heat resistance, and improvement of the adhesiveness between the piezoelectric particles 36 and the electrode layer can be obtained.

The piezoelectric layer 20 is a polymer-based piezoelectric composite material in which the piezoelectric particles 36 are dispersed in the matrix 34.

The piezoelectric particles 36 consist of ceramics particles having a perovskite type or wurtzite type crystal structure. As the ceramics particles forming the piezoelectric particles 36, for example, lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃) are exemplified. Only one of these piezoelectric particles 36 may be used, or a plurality of types thereof may be used in combination (mixture).

The particle diameter of such piezoelectric particles 36 is not limited, and may be appropriately selected depending on the size of the piezoelectric film 10, the applications of the piezoelectric film 10, and the like. The particle diameter of the piezoelectric particles 36 is preferably in a range of 0.5 to 5 μm. By setting the particle diameter of the piezoelectric particles 36 to be in this range, a preferable result is able to be obtained from a viewpoint of allowing the piezoelectric film 10 to achieve both high piezoelectric characteristics and flexibility.

Here, in the example illustrated in FIG. 1, the piezoelectric particles 36 are illustrated in a spherical shape, but the shape of the piezoelectric particles 36 is not limited to a perfect sphere, and the piezoelectric particles have various shapes. For example, as illustrated in FIG. 2, the shape has corners. As for the shape of the piezoelectric particles 36, the circularity of the piezoelectric particles observed in a cross section of the piezoelectric layer in the thickness direction is preferably in a range of 0.65 to 0.92. The circularity is expressed by “4π×(area)÷(circumference length)²” and represents the complexity of the shape. The circularity is 1 in a case of a perfect circle, and the numerical value of the circularity decreases as the shape is more complicated.

In FIG. 1, the piezoelectric particles 36 in the piezoelectric layer 20 are uniformly dispersed in the matrix 34 with regularity, but the present invention is not limited thereto. That is, the piezoelectric particles 36 in the piezoelectric layer 20 may be irregularly dispersed in the matrix 34 as long as the piezoelectric particles 36 are preferably uniformly dispersed therein.

In the piezoelectric film 10, the ratio between the amount of the matrix 34 and the amount of the piezoelectric particles 36 in the piezoelectric layer 20 is not limited and may be appropriately set according to the size and the thickness of the piezoelectric film 10 in the plane direction, the applications of the piezoelectric film 10, the characteristics required for the piezoelectric film 10, and the like. The volume fraction of the piezoelectric particles 36 in the piezoelectric layer 20 is preferably in a range of 30% to 80%, more preferably 50% or greater, and still more preferably in a range of 50% to 80%. By setting the ratio between the amount of the matrix 34 and the amount of the piezoelectric particles 36 to be in the above-described ranges, preferable results in terms of achieving both of excellent piezoelectric characteristics and flexibility can be obtained.

In the piezoelectric film 10 described above, as a preferred embodiment, the piezoelectric layer 20 is a polymer-based piezoelectric composite material in which piezoelectric particles are dispersed in the viscoelastic matrix containing a polymer material having viscoelasticity at room temperature. However, the present invention is not limited thereto, and a polymer-based piezoelectric composite material in which piezoelectric particles are dispersed in a matrix containing a polymer material, which is used in a known piezoelectric element, can be used as a piezoelectric layer.

Further, the thickness of the piezoelectric layer 20 is not particularly limited and may be appropriately set according to the applications of the piezoelectric film 10, the characteristics required for the piezoelectric film 10, and the like. The thicker the piezoelectric layer 20, the more advantageous it is in terms of rigidity such as the stiffness of a so-called sheet-like material, but the voltage (potential difference) required to stretch and contract the piezoelectric film 10 by the same amount increases. The thickness of the piezoelectric layer 20 is preferably in a range of 10 to 300 μm, more preferably in a range of 20 to 200 μm, and still more preferably in a range of 30 to 150 μm. By setting the thickness of the piezoelectric layer 20 to be in the above-described range, preferable results in terms of achieving both ensuring of the rigidity and moderate elasticity can be obtained.

<Protective Layer>

The first protective layer 28 and the second protective layer 30 in the piezoelectric film 10 have a function of coating the second electrode layer 26 and the first electrode layer 24 and imparting moderate rigidity and mechanical strength to the piezoelectric layer 20. That is, the piezoelectric layer 20 consisting of the matrix 34 and the piezoelectric particles 36 in the piezoelectric film 10 exhibits extremely excellent flexibility under bending deformation at a slow vibration, but may have insufficient rigidity or mechanical strength depending on the applications. As a compensation for this, the piezoelectric film 10 is provided with the first protective layer 28 and the second protective layer 30.

The first protective layer 28 and the second protective layer 30 are not limited, and various sheet-like materials can be used, and suitable examples thereof include various resin films. Among these, from the viewpoints of excellent mechanical characteristics and heat resistance, a resin film consisting of polyethylene terephthalate (PET), polypropylene (PP), polystyrene (PS), polycarbonate (PC), polyphenylene sulfide (PPS), polymethylmethacrylate (PMMA), polyetherimide (PEI), polyimide (PI), polyethylene naphthalate (PEN), triacetyl cellulose (TAC), and a cyclic olefin-based resin is suitably used.

The thickness of the first protective layer 28 and the second protective layer 30 is not limited. In addition, the thicknesses of the first protective layer 28 and the second protective layer 30 are basically the same as each other, but may be different from each other. Here, in a case where the rigidity of the first protective layer 28 and the second protective layer 30 is extremely high, not only is the stretch and contraction of the piezoelectric layer 20 constrained, but also the flexibility is impaired. Therefore, it is advantageous that the thickness of the first protective layer 28 and the thickness of the second protective layer 30 decrease except for the case where the mechanical strength or satisfactory handleability as a sheet-like material is required.

In a case where the thickness of the first protective layer 28 and the second protective layer 30 in the piezoelectric film 10 is two times or less the thickness of the piezoelectric layer 20, preferable results in terms of achieving both ensuring of the rigidity and moderate elasticity can be obtained.

For example, in a case where the thickness of the piezoelectric layer 20 is 50 μm and the first protective layer 28 and the second protective layer 30 consist of PET, the thickness of the first protective layer 28 and the second protective layer 30 is preferably 100 μm or less, more preferably 50 μm or less, and still more preferably 25 μm or less.

<Electrode Layer>

In the piezoelectric film 10, the first electrode layer 24 is formed between the piezoelectric layer 20 and the first protective layer 28, and the second electrode layer 26 is formed between the piezoelectric layer 20 and the second protective layer 30. The first electrode layer 24 and the second electrode layer 26 are provided to apply a voltage to the piezoelectric layer 20 (piezoelectric film 10).

In the present invention, the material for forming the first electrode layer 24 and the second electrode layer 26 is not limited, and various conductors can be used as the material. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Among these, copper, aluminum, gold, silver, platinum, and indium tin oxide are suitable as the material of the first electrode layer 24 and the second electrode layer 26.

In addition, a method of forming the first electrode layer 24 and the second electrode layer 26 is not limited, and various known methods, for example, a vapor-phase deposition method (a vacuum film forming method) such as vacuum vapor deposition, ion-assisted vapor deposition, or sputtering, a film forming method of using plating, and a method of bonding a foil formed of the materials described above can be used.

Among these, particularly from the viewpoint of ensuring the flexibility of the piezoelectric film 10, a thin film made of copper, aluminum, or the like formed by vacuum vapor deposition is suitably used as the first electrode layer 24 and the second electrode layer 26. Among these, particularly a thin film made of copper formed by vacuum vapor deposition is suitably used.

The thicknesses of the first electrode layer 24 and the second electrode layer 26 are not limited. In addition, the thicknesses of the first electrode layer 24 and the second electrode layer 26 are basically the same as each other, but may be different from each other.

Here, similarly to the first protective layer 28 and the second protective layer 30 described above, in a case where the rigidity of the first electrode layer 24 and the second electrode layer 26 is extremely high, not only is the stretch and contraction of the piezoelectric layer 20 constrained, but also the flexibility is impaired. Therefore, from the viewpoints of the flexibility and the piezoelectric characteristics, the first electrode layer 24 and the second electrode layer 26 are more advantageous as the thicknesses thereof decrease. That is, it is preferable that the first electrode layer 24 and the second electrode layer 26 are thin film electrodes.

The thickness of each of the first electrode layer 24 and the second electrode layer 26 is less than the thickness of the protective layer, and is preferably in a range of 0.05 μm to 10 μm, more preferably in a range of 0.05 μm to 5 μm, still more preferably in a range of 0.08 μm to 3 μm, and particularly preferably in a range of 0.1 μm to 2 μm.

It is suitable that the product of the thickness and the Young's modulus of the first electrode layer 24 and the second electrode layer 26 of the piezoelectric film 10 is less than the product of the thickness and the Young's modulus of the first protective layer 28 and the second protective layer 30 from the viewpoint that the flexibility is not considerably impaired.

For example, in a combination in which the first protective layer 28 and the second protective layer 30 are made of PET (Young's modulus: approximately 6.2 GPa) and the first electrode layer 24 and the second electrode layer 26 consist of copper (Young's modulus: approximately 130 GPa), in a case where the thickness of the first protective layer 28 and the second protective layer 30 is assumed to be 25 μm, the thickness of the first electrode layer 24 and the second electrode layer 26 is preferably 1.2 μm or less, more preferably 0.3 μm or less, and still more preferably 0.1 μm or less.

As described above, it is preferable that the piezoelectric film 10 has a configuration in which the piezoelectric layer 20 obtained by dispersing the piezoelectric particles 36 in the matrix 34 containing the polymer material that has a viscoelasticity at room temperature is sandwiched between the first electrode layer 24 and the second electrode layer 26 and this laminate is sandwiched between the first protective layer 28 and the second protective layer 30.

It is preferable that, in such a piezoelectric film 10, the maximal value of the loss tangent (tans) at a frequency of 1 Hz according to dynamic viscoelasticity measurement is present at room temperature and more preferable that the maximal value at which the loss tangent is 0.1 or greater is present at room temperature. In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 10, it is preferable that the storage elastic modulus (E′) at a frequency of 1 Hz according to the dynamic viscoelasticity measurement is in a range of 10 to 30 GPa at 0° C. and in a range of 1 to 10 GPa at 50° C. The same applies to the conditions for the piezoelectric layer 20. In this manner, the piezoelectric film 10 may have large frequency dispersion in the storage elastic modulus (E′). That is, the piezoelectric film 10 can exhibit a behavior of being rigid with respect to a vibration of 20 Hz to 20 kHz and being flexible with respect to a vibration of less than or equal to a few Hz.

In the piezoelectric film 10, it is preferable that the product of the thickness and the storage elastic modulus (F) at a frequency of 1 Hz according to the dynamic viscoelasticity measurement is in a range of 1.0×10⁶ to 2.0×10⁶ N/m at 0° C. and in a range of 1.0×10⁵ to 1.0×10⁶ N/m at 50° C. The same applies to the conditions for the piezoelectric layer 20. In this manner, the piezoelectric film 10 may have moderate rigidity and mechanical strength within a range not impairing the flexibility and the acoustic characteristics.

Further, in the piezoelectric film 10, it is preferable that the loss tangent (Tanδ) at a frequency of 1 kHz at 25° C. is 0.05 or greater in a master curve obtained from the dynamic viscoelasticity measurement. The same applies to the conditions for the piezoelectric layer 20. In this manner, the frequency of a speaker formed of the piezoelectric film 10 is smooth as the frequency characteristic thereof, and thus an amount of a change in acoustic quality in a case where the lowest resonance frequency f₀ is changed according to a change in the curvature of the speaker can be decreased.

In the present invention, the storage elastic modulus (Young's modulus) and the loss tangent of the piezoelectric film 10, the piezoelectric layer 20, and the like may be measured by a known method. As an example, the measurement may be performed using a dynamic viscoelasticity measuring device DMS6100 (manufactured by SII Nanotechnology Inc.).

Examples of the measurement conditions include a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10mm (including the clamped region), and a chuck-to-chuck distance of 20 mm.

Next, an example of the method of producing the piezoelectric film 10 will be described with reference to FIGS. 9 to 12.

First, as illustrated in FIG. 9, a sheet-like material l0a in which the first electrode layer 24 is formed on the first protective layer 28 is prepared. The sheet-like material l0a may be prepared by forming a copper thin film or the like as the first electrode layer 24 on the surface of the first protective layer 28 by carrying out vacuum vapor deposition, sputtering, plating, or the like.

In a case where the first protective layer 28 is extremely thin and thus the handleability is degraded, the first protective layer 28 with a separator (temporary support) may be used as necessary. Further, a PET having a thickness of 25 μm to 100 μm or the like can be used as the separator. The separator may be removed after thermal compression bonding of the second electrode layer 26 and the second protective layer 30 and before lamination of any member on the first protective layer 28.

Meanwhile, the coating material is prepared by dissolving a polymer material serving as a material of the matrix in an organic solvent, adding the piezoelectric particles 36 such as PZT particles thereto, and stirring the solution for dispersion.

The organic solvent other than the above-described substances is not limited, and various organic solvents can be used.

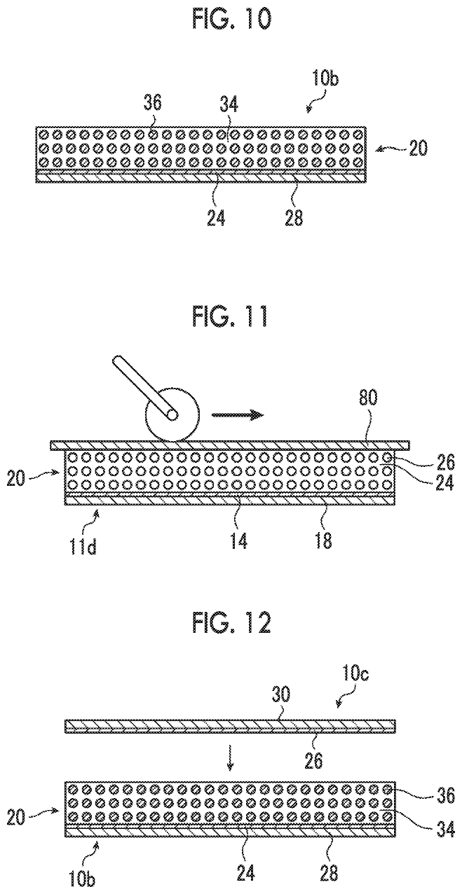

In a case where the sheet-like material 10a is prepared and the coating material is prepared, the coating material is cast (applied) onto the sheet-like material 10a, and the organic solvent is evaporated and dried. In this manner, as illustrated in FIG. 10, a laminate 10b in which the first electrode layer 24 is provided on the first protective layer 28 and the piezoelectric layer 20 is formed on the first electrode layer 24 is prepared.

A casting method of the coating material is not limited, and all known methods (coating devices) such as a slide coater or a doctor knife can be used.

As described above, in the piezoelectric film 10, in addition to the viscoelastic material such as cyanoethylated PVA, a dielectric polymer material may be added to the matrix 34.

In a case where the polymer material is added to the matrix 34, the polymer material added to the coating material may be dissolved.

Next, the piezoelectric layer 20 is set to have a desired surface shape by performing a calender treatment on the piezoelectric layer 20 of the formed laminate 10b.

Specifically, as illustrated in FIG. 11, a film 80 for a calender treatment is placed on the surface of the piezoelectric layer 20, and the film 80 for a calender treatment is pressed by a roller from above, and the shape of irregularities on the surface of the film 80 for a calender treatment is transferred to the surface of the piezoelectric layer 20. That is, a film that has projections having a height of 1 μm or greater with a number density of 100 to 1,000 pc/mm²and has a kurtosis Rku of 2.9 to 25 on the surface of the piezoelectric layer 20 after the transfer may be used as the film 80 for a calender treatment.

The surface of the piezoelectric layer 20 having a plurality of recesses with a depth of 1 μm or greater, a number density of the recesses of 100 to 1,000 pc/mm², and a kurtosis Rku of 2.9 to 25 is formed by the calender treatment.

As the film 80 for a calender treatment, a resin film such as a PET film, polypropylene, or polyvinyl chloride, and metal foil such as copper foil or aluminum foil can be used. Further, as a method of forming the surface shape of the film 80 for a calender treatment into a desired shape, a pre-calender treatment performed by the film 80 for a calender treatment, processing with abrasive paper, or the like can be used.

In addition, it is preferable that the piezoelectric layer 20 is subjected to a polarization treatment (poling) after formation of the laminate 10b and after the calender treatment.

A method of performing the polarization treatment on the piezoelectric layer 20 is not limited, and a known method can be used.

In this manner, while the piezoelectric layer 20 of the laminate 10b is subjected to the polarization treatment, a sheet-like material 10c in which the second electrode layer 26 is formed on the second protective layer 30 is prepared. The sheet-like material 10c may be prepared by forming a copper thin film or the like as the second electrode layer 26 on the surface of the second protective layer 30 using vacuum vapor deposition, sputtering, plating, or the like.

Next, as illustrated in FIG. 12, the sheet-like material 10c is laminated on the laminate 10b in which the polarization treatment performed on the piezoelectric layer 20 is completed in a state where the second electrode layer 26 is directed toward the piezoelectric layer 20.

Further, a laminate of the laminate 10b and the sheet-like material 10c is subjected to the thermal compression bonding using a heating press device, a pair of heating rollers, or the like such that the laminate is sandwiched between the second protective layer 30 and the first protective layer 28, thereby preparing the piezoelectric film 10. In addition, the laminate may be cut into a desired shape after the thermal compression bonding.

Further, the steps described so far can also be performed by using a web-like material, that is, a material wound up in a state where long sheets are connected without using a sheet-like material, during transport. Both the laminate 10b and the sheet-like material 10c have a web shape and can be subjected to thermal compression bonding as described above. In that case, the piezoelectric film 10 is prepared in a web shape at this time point.

Further, an adhesive layer may be provided in a case where the laminate 10b and the sheet-like material 10c are bonded to each other. For example, an adhesive layer may be provided on the surface of the second electrode layer 26 of the sheet-like material 10c. The most suitable adhesive layer is formed of the same material as the material of the matrix 34. The piezoelectric layer 20 may be coated with the same material or the surface of the second electrode layer 26 can be coated with the same material and bonded.

Even in a case where the adhesive layer is provided, the surface of the adhesive layer has roughness that follows the surface properties of the piezoelectric layer (piezoelectric layer main body) 20 of the laminate 10b described above. Therefore, in a case where the adhesive layer is provided, the number density of recesses on the surface of the adhesive layer and the kurtosis Rku are in the above-described ranges.

Further, a method of adjusting the number density of the recesses on the surface of the piezoelectric layer and the kurtosis Rku to be in the above-described ranges is not limited to the description above, and examples thereof include a method of bringing a roller into direct contact with the piezoelectric layer without using the film for a calender treatment in a case of the calender treatment and transferring the surface shape of the roller, a method of performing patterning in a case of application of a coating material, a method of adjusting the conditions for drying the coating film that is formed into the piezoelectric layer, a method of adjusting the thickness of the piezoelectric layer, and a method of adjusting the viscosity and the concentration of the coating material that is formed into the piezoelectric layer. The number density of recesses and the kurtosis Rku may be adjusted by combining a plurality of these methods.

Examples of performing patterning in a case of application of a coating material include a method of providing irregularities on a slide coater to provide the irregularities on a coating solution (coating film) before drying, a method of transferring the irregularity shape immediately after transporting the slide coater, and a method of performing scratching with a jig having an irregularity shape.

Further, the number density of the recesses and the kurtosis Rku can be adjusted by convection due to a difference in temperature of the coating film that is formed into the piezoelectric layer in the thickness direction. Specifically, convection in which the coating material inside the coating film moves to the surface side occurs by blowing air to the surface of the coating film in a case of drying the coating film and/or placing the sheet-like material 10a on a hot plate to provide a difference in temperature of the coating film that is formed into the piezoelectric layer 20 in the thickness direction of the coating film, and the roughness on the surface of the piezoelectric layer to be formed is changed.

In this case, the number density of the recesses and the kurtosis Rku can be adjusted by appropriately adjusting the thickness, the viscosity, and the like of the coating film that is formed into the piezoelectric layer to adjust the irregularities formed on the surface of the coating film that is formed into the piezoelectric layer.

In the above-described preparation method, one electrode layer (sheet-like material) and the piezoelectric layer are subjected to thermocompression bonding, but the present invention is not limited thereto, and the piezoelectric film may be prepared by preparing the piezoelectric layer on a temporary support and thermocompression-bonding the sheet-like materials on both surfaces of the piezoelectric layer. In this case, it is preferable that the number density of recesses on the surface and the kurtosis Rku on both surfaces of the piezoelectric layer are in the above-described ranges.

Here, a typical piezoelectric film consisting of a polymer material such as polyvinylidene difluoride (PVDF) has in-plane anisotropy as a piezoelectric characteristic and is anisotropic in the amount of expansion and contraction in the plane direction in a case where a voltage is applied.

On the contrary, the piezoelectric layer which is included in the piezoelectric film according to the embodiment of the present invention and consists of a polymer-based piezoelectric composite material that contains piezoelectric particles in a matrix containing a polymer material has no in-plane anisotropy as a piezoelectric characteristic and stretches and contracts isotropically in all directions in the in-plane direction. According to the piezoelectric film 10 that stretches and contracts isotropically and two-dimensionally as described above, the piezoelectric film can be vibrated with a larger force and a louder and more beautiful sound can be generated as compared with a case of a typical piezoelectric film formed of PVDF or the like that stretches and contracts greatly in only one direction.

Further, the piezoelectric film according to the embodiment of the present invention can also be used as a speaker of a display device, for example, by being bonded to a display device having flexibility such as an organic electroluminescence display having flexibility or a liquid crystal display having flexibility.

Further, for example, in a case where the piezoelectric film 10 is used as a speaker, the piezoelectric film 10 may be used as a speaker that generates a sound from the vibration of the film-like piezoelectric film. Alternatively, the piezoelectric film 10 may be used as an exciter that generates a sound by being attached to a vibration plate to vibrate the vibration plate, from the vibration of the piezoelectric film 10.

In addition, the piezoelectric film 10 according to the embodiment of the present invention satisfactorily functions as a piezoelectric vibrating element that vibrates a vibrating body such as a vibration plate by laminating a plurality of the piezoelectric films to obtain a laminated piezoelectric element.

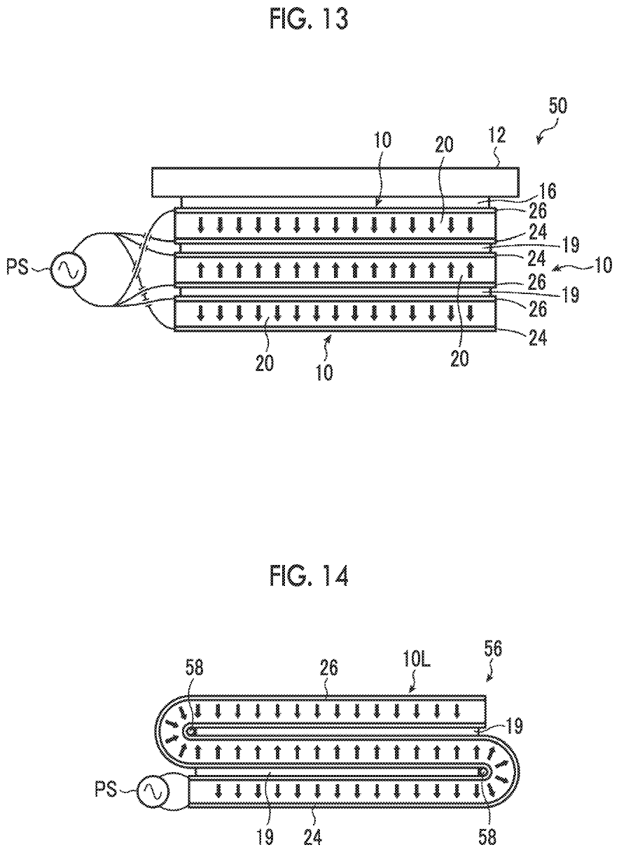

As an example, as illustrated in FIG. 13, the laminated piezoelectric element 50 obtained by laminating the piezoelectric films 10 is bonded to the vibration plate 12 and may be used as a speaker that allows the laminate of the piezoelectric films 10 to vibrate the vibration plate 12 and outputs a sound. That is, in this case, the laminate of the piezoelectric film 10 acts as a so-called exciter that outputs a sound by vibrating the vibration plate 12.

By applying a driving voltage to the laminated piezoelectric element 50 obtained by laminating the piezoelectric films 10, each of the piezoelectric films 10 stretches and contracts in the plane direction, and the entire laminate of the piezoelectric films 10 stretches and contracts in the plane direction due to the stretch and contraction of each of the piezoelectric films 10. The vibration plate 12 to which the laminate has been bonded is bent due to the stretch and contraction of the laminated piezoelectric element 50 in the plane direction, and as a result, the vibration plate 12 vibrates in the thickness direction. The vibration plate 12 generates a sound due to the vibration in the thickness direction. That is, the vibration plate 12 vibrates according to the magnitude of the driving voltage applied to the piezoelectric film 10, and generates a sound according to the driving voltage applied to the piezoelectric film 10. Therefore, the piezoelectric film 10 itself does not output sound in this case.

Therefore, even in a case where the rigidity of each piezoelectric film 10 is low and the stretching and contracting force thereof is small, the rigidity of the laminated piezoelectric element 50 obtained by laminating the piezoelectric films 10 is increased, and the stretching and contracting force as the entire laminate is increased. As a result, in the laminated piezoelectric element 50 obtained by laminating the piezoelectric films 10, even in a case where the vibration plate has a certain degree of rigidity, the vibration plate 12 is sufficiently bent with a large force and can be sufficiently vibrated in the thickness direction, and thus the vibration plate 12 can generate a sound.

In the laminated piezoelectric element 50 obtained by laminating the piezoelectric films 10, the number of laminated sheets of the piezoelectric films 10 is not limited, and the number of sheets set such that a sufficient amount of vibration is obtained may be appropriately set according to, for example, the rigidity of the vibration plate 12 to be vibrated. Further, one piezoelectric film 10 can also be used as a similar exciter (piezoelectric vibrating element) in a case where the piezoelectric film 10 has a sufficient stretching and contracting force.

The vibration plate 12 that is vibrated by the laminated piezoelectric element 50 obtained by laminating the piezoelectric films 10 is not limited, and various sheet-like materials (plate-like materials and films) can be used. Examples thereof include a resin film consisting of polyethylene terephthalate (PET) and the like, foamed plastic consisting of foamed polystyrene and the like, a paper material such as a corrugated cardboard material, a glass plate, and wood. Further, various machines (devices) such as display devices such as an organic electroluminescence display and a liquid crystal display may be used as the vibration plate as long as the devices can be sufficiently bent.

It is preferable that the laminated piezoelectric element 50 obtained by laminating the piezoelectric films 10 is formed by bonding the adjacent piezoelectric films 10 with a bonding layer 19 (bonding agent). Further, it is preferable that the laminated piezoelectric element 50 and the vibration plate 12 are also bonded with a bonding layer 16.

The bonding layer is not limited, and various layers that can bond materials to be bonded can be used. Therefore, the bonding layer may consist of a pressure sensitive adhesive or an adhesive. It is preferable that an adhesive layer consisting of an adhesive is used from the viewpoint that a solid and hard bonding layer is obtained after the bonding. The same applies to the laminate formed by folding back the long piezoelectric film 10 described later.

In the laminated piezoelectric element 50 obtained by laminating the piezoelectric films 10, the polarization direction of each piezoelectric film 10 to be laminated is not limited. It is preferable that the piezoelectric film 10 according to the embodiment of the present invention is polarized in the thickness direction. The polarization direction of the piezoelectric film 10 here is a polarization direction in the thickness direction. Therefore, in the laminated piezoelectric element 50, the polarization directions may be the same for all the piezoelectric films 10, and piezoelectric films having different polarization directions may be present.

In a laminated piezoelectric element 50 obtained by laminating the piezoelectric films 10, it is preferable that the piezoelectric films 10 are laminated such that the adjacent piezoelectric films 10 have polarization directions opposite to each other. In the piezoelectric film 10, the polarity of the voltage to be applied to the piezoelectric layer 20 depends on the polarization direction of the piezoelectric layer 20. Therefore, even in a case where the polarization direction is directed from the second electrode layer 26 toward the first electrode layer 24 or from the first electrode layer 24 toward the second electrode layer 26, the polarity of the second electrode layer 26 and the polarity of the first electrode layer 24 in all the piezoelectric films 10 to be laminated are set to be the same as each other. Therefore, by reversing the polarization directions of the adjacent piezoelectric films 10, even in a case where the electrode layers of the adjacent piezoelectric films 10 come into contact with each other, the electrode layers in contact with each other have the same polarity, and thus there is no risk of a short circuit.

The laminated piezoelectric element obtained by laminating the piezoelectric films 10 may have a configuration in which a plurality of piezoelectric films 10 are laminated by folding a piezoelectric film 10L once or more times and preferably a plurality of times, as illustrated in FIG. 14. The laminated piezoelectric element 56 obtained by folding back and laminating the piezoelectric film 10 has the following advantages.

In the laminate in which a plurality of cut sheet-like piezoelectric films 10 are laminated, the second electrode layer 26 and the first electrode layer 24 need to be connected to a driving power supply for each piezoelectric film. On the contrary, in the configuration in which the long piezoelectric film 10L is folded back and laminated, only one sheet of the long piezoelectric film 10L can form the laminated piezoelectric element 56. Therefore, in the configuration in which the long piezoelectric film 10L is folded back and laminated, only one power source is required for applying the driving voltage, and the electrode may be led out from the piezoelectric film 10L at one site. Further, in the configuration in which the long piezoelectric film 10L is folded back and laminated, the polarization directions of the adjacent piezoelectric films are inevitably opposite to each other.

Further, such a laminated piezoelectric element obtained by laminating the piezoelectric film including electrode layers and protective layers provided on both surfaces of a piezoelectric layer consisting of a polymer-based piezoelectric composite material is described in WO2020/095812A and WO2020/179353A.

Hereinbefore, the piezoelectric film according to the embodiment of the present invention has been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention. Further, the present invention is not limited to the examples, and the materials, the used amounts, the proportions, the treatment contents, the treatment procedures, and the like shown in the following examples can be appropriately changed within a range not departing from the scope of the present invention.

### Example 1

Sheet-like materials 10a and 10c formed by sputtering a copper thin film having a thickness of 100 nm on a PET film having a thickness of 4 μm were prepared. That is, in the present example, the first electrode layer 24 and the second electrode layer 26 were copper thin films having a thickness of 100 nm, and the first protective layer 28 and the second protective layer 30 were PET films having a thickness of 4 μm.

The gas pressure during the sputtering of the copper thin film on the PET film was set to 0.4 Pa, and the base material temperature (temperature of the PET film) was set to 120° C.

Further, in order to obtain satisfactory handleability during the process, a film with a separator (temporary support PET) having a thickness of 50 μm was used as the PET film, and the separator of each protective layer was removed after the thermal compression bonding of the sheet-like material 10c.

First, cyanoethylated PVA (CR-V, manufactured by Shin-Etsu Chemical Co., Ltd.) was dissolved in methyl ethyl ketone (MEK) at the following compositional ratio. Thereafter, PZT particles were added to the solution at the following compositional ratio and dispersed using a propeller mixer (rotation speed of 2,000 rpm), thereby preparing a coating material for forming a piezoelectric layer 20.
PZT Particles: 300 parts by mass
Cyanoethylated PVA: 15 parts by mass
MEK: 85 parts by mass

In addition, PZT particles obtained by sintering commercially available PZT raw material powder at 1,000° C. to 1,200° C. and crushing and classifying the sintered powder to have an average particle diameter of 5 μm were used as the PZT particles.

The first electrode layer 24 (copper thin film) of the sheet-like material 10a prepared in advance was coated with the coating material for forming the piezoelectric layer 20 prepared in advance using a slide coater. Further, the coating material was applied such that the film thickness of the coating film after being dried reached 20 μm.

Next, the material obtained by coating the sheet-like material 10a with the coating material was placed on a hot plate at 120° C., and the coating film was heated and dried. In this manner, MEK was evaporated to form a laminate 10b.

Next, the film 80 for a calender treatment was placed on the surface of the formed piezoelectric layer 20, and the calender treatment was performed using a roller.

Further, the number density of projections having a height of 1 μm and the kurtosis Rku of the film 80 for a calender treatment were measured as follows.

The number density of projections with a height of 1 μm and the kurtosis Rku were calculated by measuring the profile of the surface roughness of the film 80 for a calender treatment under conditions of a white LED light source (green filter), an objective lens at a magnification of 10 times, an internal lens at a magnification of 0.55 times, a charge coupled device (CCD): 1,280×960 pixel, VSI/VXI, an observation visual field of 825.7 μm×619.3 μm, and a cross-section sampling of 0.645 μm using a non-contact three-dimensional surface shape roughness meter (manufactured by Bruker), setting 0 as an average value, making correction of cylinder inclination, performing fitting with Gaussian process regression, and acquiring the surface roughness. The number density of projections and the kurtosis Rku were measured for each of 10 observation visual fields, and the average value was acquired. The measurement results are listed in Table 1.

Next, the sheet-like material 10c was laminated on the laminate 10b in a state where the second electrode layer 26 (copper thin film side) side was oriented to the piezoelectric layer 20, and subjected to thermal compression bonding at 120° C.

In this manner, a piezoelectric film 10 including the first protective layer 28, the first electrode layer 24, the piezoelectric layer 20, the second electrode layer 26, and the second protective layer 30 in this order was prepared.

A 5 mol/L NaOH aqueous solution was added dropwise to the second protective layer 30 of the prepared piezoelectric film 10 at 15° C. to 25° C. for dissolution. Here, even in a case where a part of the second electrode layer 26 was dissolved, the electrode layer 20 was allowed to stand for a time during which the NaOH aqueous solution did not come into contact with the piezoelectric layer. The second protective layer 30 was dissolved and washed with pure water. Next, the exposed second electrode layer 26 was dissolved in a 0.01 mol/L ferric chloride aqueous solution. The dissolution in the ferric chloride aqueous solution was set such that the time after the exposure of the piezoelectric layer 20 did not exceed 5 minutes. The exposed piezoelectric layer 20 was washed with pure water and dried at 30° C. or lower.

Next, the number density of recesses, the kurtosis Rku, and the surface roughness Ra were calculated by measuring the exposed surface of the piezoelectric layer 20 under conditions of a white LED light source (green filter), an objective lens at a magnification of 10 times, an internal lens at a magnification of 0.55 times, CCD: 1,280×960 pixel, VSI/VXI, an observation visual field of 825.7 μm x 619.3 μm, and a cross-section sampling of 0.645 μm using a non-contact three-dimensional surface shape roughness meter (manufactured by Bruker), setting 0 as an average value, making correction of cylinder inclination, performing fitting with Gaussian process regression, and acquiring the surface roughness. The number density of recesses, the kurtosis Rku, and the surface roughness Ra were measured for each of 10 observation visual fields, and the average value was acquired. The measurement results are listed in Table 1.

The particle diameter of the piezoelectric particles 36 in the piezoelectric layer 20 was measured as follows.

A sample is cut out from the piezoelectric film and machined in the thickness direction for observation of a cross section. The piezoelectric film is machined by mounting a histo knife blade (manufactured by Drukker) having a width of 8 mm on RM2265 (manufactured by Leica Biosystems) and setting the speed to a controller scale of 1 and an engagement amount of 0.25 to 1 μm.

Next, the cross section is observed with a scanning electron microscope (SEM) using the sample with the cross section that has been processed. For example, S-4800 (manufactured by Hitachi High-Tech Corporation) can be used as the SEM. In addition, the sample may be subjected to a conductive treatment. For example, the sample is subjected to a conductive treatment with platinum vapor deposition, and the work distance may be set to 2.8 mm.

The observation is carried out with a secondary-electron (SE) image by setting an SE detector to upper (U) and +BSE L. A. 100. The observation is carried out under conditions of an acceleration voltage of 2 kV and a probe current of high, focus adjustment and astigmatism adjustment are performed produce a sharpest image, and automatic brightness adjustment (auto setting brightness: 0, contrast: 0) is performed in a state where the piezoelectric film covers the entire screen.

The imaging magnification is set as the magnification such that the first electrode layer and the second electrode layer fit on one screen and the width between the electrodes reaches a half or greater of the screen. Here, an image is captured such that two electrode layers are horizontal to the lower portion of the image.

The image acquired as described above is binarized. Specifically, first, linear conversion is made by setting the density range of the original imaging data to be in a gradation range of 0 (dark) to 255 (bright) using image analysis software WinROOF, to enhance the contrast. Subsequently, the piezoelectric layer is selected in a rectangular shape so that the selected area is maximized in a range not including the first electrode layer and the second electrode layer, and a portion in gradation with a density range of 110 to 255 is binarized.

The average particle diameter of the piezoelectric particles is obtained by acquiring the circle-equivalent diameter of each piezoelectric particle using an image binarized by the above-described method and calculating the average value thereof. The N5 visual field measurement of the cross section is also performed for the average particle diameter, and the average particle diameter is acquired for each measurement visual field and defined as the average particle diameter of the piezoelectric particles in the piezoelectric film.

The measurement results are listed in Table 1.

### Example 2

A piezoelectric film was prepared in the same manner as in Example 1 except that the average particle diameter of the PZT particles dispersed in the coating material formed into the piezoelectric layer was set to 5.75 μm. The kurtosis Rku and the surface roughness Ra of the piezoelectric layer of the prepared piezoelectric film, and the particle diameter of the piezoelectric particles were measured by the same method as described above.

### Example 3

A piezoelectric film was prepared in the same manner as in Example 1 except that a film having the number density of projections and the kurtosis Rku described below was used as the film 80 for a calender treatment.

The number density of the projections and the kurtosis Rku of the film 80 for a calender treatment are as listed in Table 1.

### Comparative Examples 1 to 5

Piezoelectric films were prepared in the same manner as in Example 1 except that different resin films were respectively used as the film 80 for a calender treatment.

The number density of the projections and the kurtosis Rku of each film 80 for a calender treatment are as listed in Table 1.

### Evaluation

First, a circular test piece having a diameter of 150 mm was cut out from the prepared piezoelectric film. The test piece was fixed to cover the opening surface of a round plastic case having an inner diameter of 138 mm and a depth of 9 mm, and the pressure inside the case was maintained at 1.02 atm. In this manner, the piezoelectric film was bent into a convex shape like a contact lens to form a piezoelectric speaker.

A 1 kHz sine wave was input to the prepared piezoelectric speaker as an input signal through a power amplifier, and the sound pressure (initial sound pressure) was measured with a microphone placed at a distance of 50 cm from the center of the speaker.

Next, an operation of bending the prepared piezoelectric film from an opening angle of 180° to 90° and returning the film to an angle of 180° was repeated 100 times, the piezoelectric film was incorporated into the piezoelectric speaker in the same manner as described above, and the sound pressure (sound pressure after a bending durability test) was measured.

The results are listed in Table 1.

TABLE 1

| | Film for calender treatment | | Piezoelectric layer | | | | Evaluation: sound pressure | | |
|---|---|---|---|---|---|---|---|---|---|
| | Number density | | Number density | | Particle | | | After bending | |
| | of projections | | of recesses | | diameter | Ra | Initial | durability test | |
| | [pc/mm²] | Rku | [pc/mm²] | Rku | [μm] | [nm] | [dB] | [dB] | Difference |
| Comparative | 4098 | 3.015 | 2335 | 2.845 | 1.41 | 192.659 | 52 | 51 | 1 |
| Example 1 | | | | | | | | | |
| Comparative | 580.2 | 35.932 | 354 | 30.998 | 1.45 | 61.098 | 89 | 63 | 26 |
| Example 2 | | | | | | | | | |
| Comparative | 328.4 | 2.987 | 238.9 | 2.565 | 1.42 | 129.012 | 67 | 54 | 13 |
| Example 3 | | | | | | | | | |
| Comparative | 195 | 16.02 | 96 | 14.82 | 1.44 | 150.501 | 89 | 65 | 24 |
| Example 4 | | | | | | | | | |
| Comparative | 2175 | 4.812 | 1518 | 3.709 | 1.49 | 189.245 | 53 | 51 | 2 |
| Example 5 | | | | | | | | | |
| Example 1 | 368.7 | 5.23 | 183.9 | 3.129 | 1.43 | 98.932 | 89 | 87 | 2 |
| Example 2 | 368.7 | 5.23 | 168.4 | 3.671 | 5.75 | 197.294 | 85 | 81 | 4 |
| Example 3 | 1287 | 34.961 | 976.2 | 22.987 | 1.50 | 298.058 | 77 | 76 | 1 |

As listed in Table 1, it was found that in the piezoelectric element of the present invention, the difference between the initial sound pressure and the sound pressure after the durability test was small and the durability against the bending and stretching was high as compared with the comparative examples.

In Comparative Example 1, it was considered that since the number density of the recesses was extremely large and the kurtosis Rku was extremely small, the filling ratio of the piezoelectric layer was decreased, and the initial sound pressure was decreased.

In Comparative Example 2, it was considered that since the kurtosis Rku was extremely large and stress concentration on the tip portions of the recesses occurred, the piezoelectric layer was damaged, and thus the sound pressure after the durability test was decreased.

In Comparative Example 3, it was considered that since the kurtosis Rku was extremely small, the filling ratio of the piezoelectric layer was decreased, and the initial sound pressure was decreased.

In Comparative Example 4, it was considered that since the number density of the recesses was extremely small, the piezoelectric particles were damaged in a case where the compressive stress was applied to the piezoelectric layer, and thus the sound pressure after the durability test was decreased.

In Comparative Example 5, it was considered that since the number density of the recesses was extremely large, the filling ratio of the piezoelectric layer was decreased, and the initial sound pressure was decreased.

Based on the comparison between Examples 1 and 2, it was found that the particle diameter of the piezoelectric particles is preferably in a range of 0.5 μm to 5 μm.

Further, based on the comparison between Examples 1 and 3, it was found that the surface roughness Ra of the piezoelectric layer is preferably in a range of 10 nm to 200 nm.

As shown in the above-described results, the effects of the present invention are evident.

The piezoelectric film according to the embodiment of the present invention can be suitably used for various applications, for example, various sensors (particularly useful for infrastructure inspection such as crack detection and inspection at a manufacturing site such as foreign matter contamination detection) such as sound wave sensors, ultrasound sensors, pressure sensors, tactile sensors, strain sensors, and vibration sensors, acoustic devices (specific applications thereof include noise cancellers (used for cars, trains, airplanes, robots, and the like), artificial voice cords, buzzers for preventing invasion of pests and harmful animals, furniture, wallpaper, photos, helmets, goggles, headrests, signage, and robots) such as microphones, pickups, speakers, and exciters, haptics used by being applied to automobiles, smartphones, smart watches, and game machines, ultrasonic transducers such as ultrasound probes and hydrophones, actuators used for water droplet adhesion prevention, transport, stirring, dispersion, and polishing, damping materials (dampers) used for containers, vehicles, buildings, and sports goods such as skis and rackets, and vibration power generation devices used by being applied to roads, floors, mattresses, chairs, shoes, tires, wheels, personal computer keyboards, and the like.

### EXPLANATION OF REFERENCES

10, 10L: piezoelectric film
10a, 10c: sheet-like material
10b: laminate
12: vibration plate
16, 19: bonding layer
20: piezoelectric layer
24: first electrode layer
26: second electrode layer
28: first protective layer
30: second protective layer
34: matrix
36: piezoelectric particle
50, 56: laminated piezoelectric element
58: core rod

What is claimed is:

1. A piezoelectric film comprising:
a piezoelectric layer consisting of a polymer-based piezoelectric composite material that contains piezoelectric particles in a matrix containing a polymer material; and
electrode layers formed on both surfaces of the piezoelectric layer,
wherein at least one surface of the piezoelectric layer has a plurality of recesses with a depth of 1 μm or greater,
the recesses have a number density of 100 to 1,000 pc/mm², and
the at least one surface has a kurtosis Rku of 2.9 to 25.

2. The piezoelectric film according to claim 1,
wherein the piezoelectric particles have an average particle diameter of 0.5 μm to 5 μm.

3. The piezoelectric film according to claim 1,
wherein the at least one surface of the piezoelectric layer has a surface roughness Ra of 10 nm to 200 nm.

4. The piezoelectric film according to claim 1,
wherein the piezoelectric layer includes a piezoelectric layer main body and an interlayer.

5. The piezoelectric film according to claim 2,
wherein the at least one surface of the piezoelectric layer has a surface roughness Ra of 10 nm to 200 nm.

6. The piezoelectric film according to claim 2,
wherein the piezoelectric layer includes a piezoelectric layer main body and an interlayer.

7. The piezoelectric film according to claim 3,
wherein the piezoelectric layer includes a piezoelectric layer main body and an interlayer.
